(19) United States
(12) Patent Application Publication
(10) Pub. No.: US 2013/0248886 A1
(43) Pub. Date: Sep. 26, 2013

(54) SEMICONDUCTOR DEVICE AND SEMICONDUCTOR MODULE

(71) Applicant: KABUSHIKI KAISHA TOSHIBA, Tokyo (JP)

(72) Inventor: Mitsuhiko KITAGAWA, Tokyo (JP)

(73) Assignee: Kabushiki Kaisha Toshiba, Tokyo (JP)

(21) Appl. No.: 13/754,602

(22) Filed: Jan. 30, 2013

(30) Foreign Application Priority Data
Mar. 26, 2012 (JP) 2012-070000
Oct. 30, 2012 (JP) 2012-238886

(51) Int. Cl. H01L 29/06

(52) U.S. Cl. CPC H01L 29/0646
USPC 257/80; 257/368; 257/290

(57) ABSTRACT

In one embodiment, a semiconductor device includes a semiconductor substrate having first and second main surfaces, and including a first semiconductor layer of a first conductivity type in the substrate, a second semiconductor layer of a second conductivity type on a surface of the first semiconductor layer on a first main surface side, a third semiconductor layer of the first conductivity type on a surface of the second semiconductor layer, and a fourth semiconductor layer of the second conductivity type on a surface of the first semiconductor layer on a second main surface side. The device further includes a control electrode and a first main electrode on the first main surface side of the substrate, and a second main electrode and a junction termination portion on the second main surface side of the substrate, the junction termination portion having an annular planar shape surrounding the fourth semiconductor layer.

### CROSS-REFERENCE TO RELATED APPLICATIONS

This application is based upon and claims the benefit of priority from the prior Japanese Patent Applications No. 2012-070000, filed on Mar. 26, 2012 and No. 2012-238886, filed on Oct. 30, 2012, the entire contents of which are incorporated herein by reference.

### FIELD

Embodiments described herein relate to a semiconductor device and a semiconductor module.

### BACKGROUND

In a conventional power semiconductor device, a gate electrode, a source electrode (cathode electrode), an anode potential portion, and a junction termination portion are formed on the same main surface of the semiconductor substrate. Therefore, when the gate and source electrodes are connected to external electrodes, bonding wires need to be disposed across the joint termination portion and the anode potential portion. This becomes a cause of noise of signals and instability of circuit operation. Furthermore, when a plurality of semiconductor chips having such structures are placed in one package, a similar problem occurs with regard to the bonding wires which connect the chips and other circuits or the like. Especially when the noise is added to a signal for controlling the circuit operation, variations in operation occur among the chips.

### BRIEF DESCRIPTION OF THE DRAWINGS

FIG. 1 is a sectional view showing a structure of a semiconductor device of a first embodiment;

FIG. 2 is a sectional view showing a structure of a semiconductor device of a second embodiment;

FIG. 3 is a sectional view schematically showing a structure of a semiconductor module of a third embodiment;

FIG. 4 is a plan view showing the structure of the semiconductor module of the third embodiment;

FIGS. 5A to 5C are sectional views showing an outline of a method of manufacturing a semiconductor device of a fourth embodiment;

FIGS. 6A to 6C are sectional views showing an outline of a method of manufacturing a semiconductor device of a fifth embodiment;

FIGS. 7A to 7C are sectional views showing structures of semiconductor devices of a sixth embodiment;

FIGS. 8A to 10B are circuit diagrams showing examples of a structure of a semiconductor module of a seventh embodiment;

FIGS. 11 and 12 are circuit diagrams showing examples of a short-circuit protection circuit of the seventh embodiment;

FIGS. 13A and 13B are perspective views showing examples of a method of mounting semiconductor devices of the first to the seventh embodiments;

FIGS. 14A to 14C are schematic views showing examples of a method of connecting semiconductor structures of the first to the seventh embodiments;

FIG. 15 is a plan view showing a structure of a semiconductor module of a modification of the third embodiment;

FIGS. 16A and 16B are plan views schematically showing the structures of the semiconductor devices (semiconductor chips) of the first and second embodiment, respectively;

FIGS. 17A and 17B are a schematic view and a circuit diagram showing a cross section and a circuit structure of a semiconductor chip of an eighth embodiment, respectively; and

FIGS. 18 to 20 are circuit diagrams showing examples of a structure of a semiconductor module of the eighth embodiment.

### DETAILED DESCRIPTION

Embodiments will now be explained with reference to the accompanying drawings.

In one embodiment, a semiconductor device includes a semiconductor substrate having first and second main surfaces, and including a first semiconductor layer of a first conductivity type disposed in the semiconductor substrate, a second semiconductor layer of a second conductivity type disposed on a surface of the first semiconductor layer on a first main surface side, a third semiconductor layer of the first conductivity type disposed on a surface of the second semiconductor layer, and a fourth semiconductor layer of the second conductivity type disposed on a surface of the first semiconductor layer on a second main surface side. The device further includes a control electrode disposed on the first main surface side of the semiconductor substrate, and a first main electrode disposed on the first main surface side of the semiconductor substrate. The device further includes a second main electrode disposed on the second main surface side of the semiconductor substrate, and a junction termination portion disposed on the second main surface side of the semiconductor substrate and having an annular planar shape surrounding the fourth semiconductor layer.

### First Embodiment

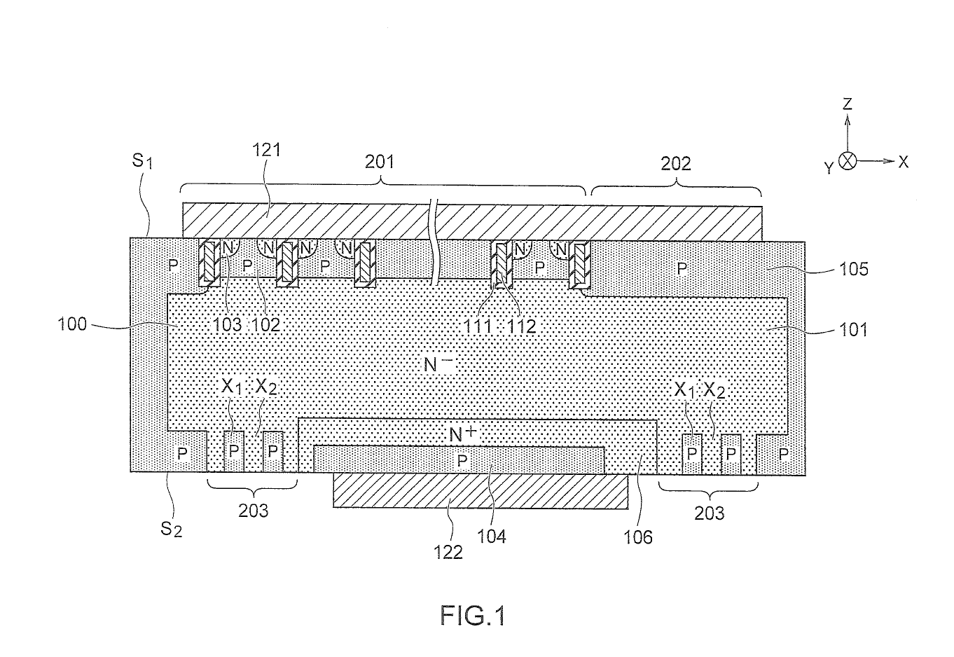

FIG. 1 is a sectional view showing a structure of a semiconductor device of a first embodiment. The device of FIG. 1 is a power semiconductor device of an opposite conductivity type.

A semiconductor substrate 100 of the device of FIG. 1 includes an N type first base layer 101 as an example of a first semiconductor layer, a P type second base layer 102 as an example of a second semiconductor layer, an N type source layer (emitter layer) 103 as an example of a third semiconductor layer, a P type drain layer (collector layer) 104 as an example of a fourth semiconductor layer, a P type peripheral diffusion layer 105 as an example of a fifth semiconductor layer, and an N+ type anode layer 106 as an example of a sixth semiconductor layer. Reference signs 201, 202 and 203 respectively denote a MOSFET portion, a diode portion and a junction termination portion in the semiconductor substrate 100.

The semiconductor device of FIG. 1 further includes gate insulators 111, gate electrodes 112, a first main electrode 121 and a second main electrode 122. Each gate electrode 112 is an example of a control electrode.

First and second conductivity types are set as the N type and the P type in the present embodiment, respectively. However, the first and second conductivity types may be set as the P type and the N type, respectively.

The semiconductor substrate 100 is, for example, a silicon substrate. Reference signs S₁ and S₂ denote a first main surface (front surface) and a second main surface (back surface) of the semiconductor substrate 100, respectively. FIG. 1 shows X and Y directions which are parallel with the main surfaces of the semiconductor substrate 100 and are perpendicular to each other, and a Z direction which is perpendicular to the main surfaces of the semiconductor substrate 100.

The first base layer 101 is a high resistive layer which occupies a major part in the semiconductor substrate 100. As shown in FIG. 1, the first base layer 101 is continuously formed in the MOSFET portion 201 and in the diode portion 202.

The second base layer 102 is formed on a surface of the first base layer 101 on the first main surface side (i.e., on the S₁ side). The source layer 103 is formed on a surface of the second base layer 102. The drain layer 104 is formed on a surface of the first base layer 101 on the second main surface side (i.e., on the S₂ side). The present embodiment may adopt a structure in which the third semiconductor layer 103 is set as a drain layer, and the fourth semiconductor layer 104 is set as a source layer.

The peripheral diffusion layer 105 is formed on side surfaces and the first and second main surfaces Sᵢ and S₂ of the semiconductor substrate 100. Portions of the peripheral diffusion layer 105 which are formed on the first main surface Sᵢ functions as cathode layers. The anode layer 106 is formed to cover the drain layer 104 between the first base layer 101 and the drain layer 104. The present embodiment may adopt a structure in which the fifth semiconductor layer 105 is set as an anode layer, and the sixth semiconductor layer 106 is set as a cathode layer.

The gate electrodes 112 are formed in trenches which are formed on the first main surface side (Sᵢ side) of the semiconductor substrate 100 via the gate insulators 111. The gate insulators 111 are, for example, silicon oxide layers. The gate electrodes 112 are, for example, polysilicon layers.

The first main electrode 121 is continuously formed on the MOSFET portion 201 and on the diode portion 202 on the first main surface side (S₁ side) of the semiconductor substrate 100. The first main electrode 121 functions as a source electrode (emitter electrode) and a cathode electrode.

The second main electrode 122 is formed at a position in contact with the drain layer 104 and the anode layer 106 on the second main surface side (S₂ side) of the semiconductor substrate 100. The second main electrode 122 functions as a drain electrode (collector electrode) and an anode electrode.

The junction termination portion 203 is formed on the second main surface side (S₂ side) of the semiconductor substrate 100. The junction termination portion 203 has an annular planar shape which surrounds the drain layer 104 and the anode layer 106 (see FIG. 16A). FIG. 16A is a plan view schematically showing the structure of the semiconductor device (semiconductor chip 300) of the first embodiment. FIG. 16A shows the semiconductor substrate 100 seen from below the second main surface S₂.

Returning to FIG. 1, the description of the semiconductor device of the first embodiment will be continued.

The junction termination portion 203 of the present embodiment is a guard ring layer, and has a structure in which one or more annular P type diffusion layers X₁ and one or more annular N type diffusion layers X₂ are alternately disposed. The N type diffusion layers X₂ correspond to portions of the first base layer 101. The P type diffusion layers X₁ correspond to layers which are formed simultaneously with the peripheral diffusion layer 105. The junction termination portion 203 may be a reduced surface (RESURF) layer which includes a diffusion layer formed on the side surface and the bottom surface of an annular insulator.

The junction termination portion 203 of the present embodiment is formed between the drain layer 104 (anode layer 106) and the peripheral diffusion layer 105. This makes it possible to prevent a depletion layer extending in the peripheral diffusion layer 105 from reaching the drain layer 104 (anode layer 106). In the present embodiment, the depletion layer in the peripheral diffusion layer 105 extends from the first main surface S₁ of the semiconductor substrate 100 to the second main surface S₂ through the side surface of the semiconductor substrate 100. The extension of the depletion layer is blocked by the junction termination portion 203 on the second main surface (S₂) side.

As described above, the gate electrodes 112 and the source electrode (first main electrode) 121 in the present embodiment are formed on the first main surface (Sᵢ) side of the semiconductor substrate 100. In contrast, the junction termination portion 203 is formed on the second main surface (S₂) side of the semiconductor substrate 100.

Therefore, according to the present embodiment, when the gate electrodes 112 and the source electrode 121 are connected to external electrodes, bonding wires do not need to be disposed across the junction termination portion 203. Therefore, according to the present embodiment, signal noise and unstable operation due to the junction termination portion 203 can be reduced.

To dispose the junction termination portion 203 on the second main surface (S₂) side, a size of the drain electrode (second main electrode) 122 is reduced in the present embodiment. The reason is to avoid contact of the junction termination portion 203 and the drain electrode 122. Therefore, when the drain electrode 122 and the junction termination portion 203 in the present embodiment are seen in plan view, an outer peripheral surface of the drain electrode 122 is located inside an inner peripheral surface of the junction termination portion 203. More specifically, the drain electrode 122 in the present embodiment is disposed inside the junction termination portion 203.

The structure of each gate electrode 112 is a trench gate type in the present embodiment. However, the structure of each gate electrode 112 may be other than the trench gate type.

### Second Embodiment

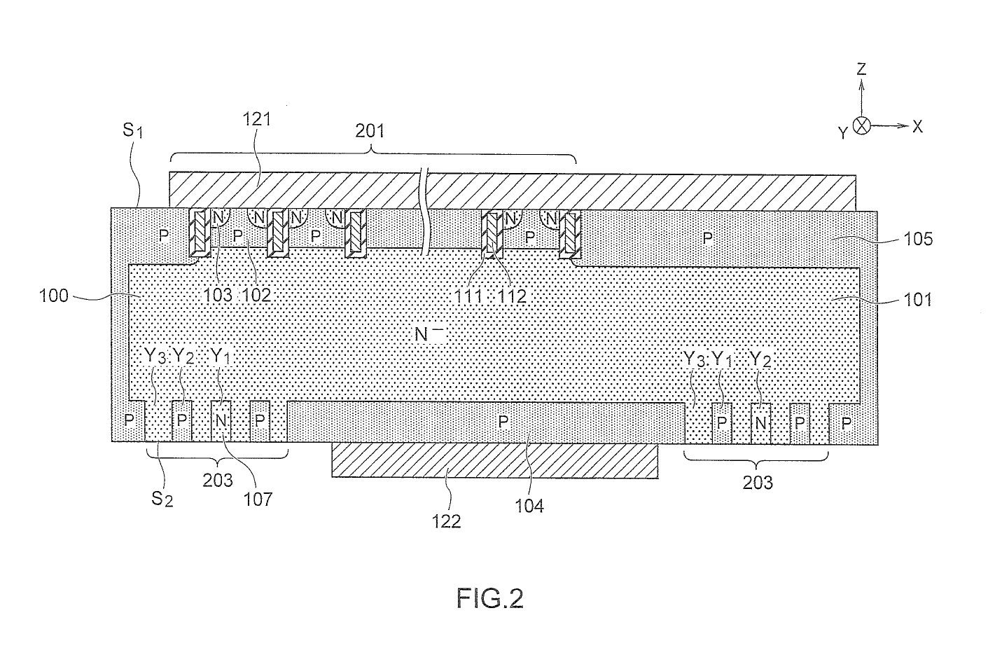

FIG. 2 is a sectional view showing a structure of a semiconductor device of a second embodiment. The device of FIG. 2 is a power semiconductor device of a forward-reverse blocking type.

Although the semiconductor device of FIG. 2 includes the MOSFET portion 201, the semiconductor device of FIG. 2 does not include the diode portion 202. Therefore, the anode layer 106 is not formed in the semiconductor substrate 100 of FIG. 2. As shown in FIG. 2, a structure in which the junction termination portion 203 is disposed on the second main surface S₂ side can be also applied to the semiconductor device without the diode portion 202.

The junction termination portion 203 is formed on the second main surface (S₂) side of the semiconductor substrate 100, and has an annular planar shape which surrounds the drain layer 104 (see FIG. 16B). FIG. 16B is a plan view schematically showing the structure of the semiconductor device (semiconductor chip 300) of the second embodiment. FIG. 16B shows the semiconductor substrate 100 seen from below the second main surface S₂.

Returning to FIG. 2, the description of the semiconductor device of the second embodiment will be continued.

The junction termination portion 203 of the present embodiment includes an annular N type diffusion layer Y₁, and one or more annular P type diffusion layers Y₂, and one or more annular N type diffusion layers Y₃ which are alternately disposed on both sides of the annular N type diffusion layer Y₁. This makes it possible to prevent the depletion layer extending in the peripheral diffusion layer 105 from reaching the drain layer 104, and to prevent a depletion layer extending in the drain layer 104 from reaching the peripheral diffusion layer 105.

The N type diffusion layer Y₁ is a diffusion layer 107 with an N type impurity concentration higher than that of the first base layer 101. The N type diffusion layers Y₃ correspond to portions of the first base layer 101. The P type diffusion layers Y₂ correspond to layers which are formed simultaneously with the peripheral diffusion layer 105.

As described above, the junction termination portion 203 in the present embodiment is formed on the second main surface (S₂) side, similarly to the first embodiment. Therefore, according to the present embodiment, when the gate electrode 112 and the source electrode (first main electrode) 121 are connected to external electrodes, bonding wires do not have to be disposed across the junction termination portions 203. Therefore, according to the present embodiment, signal noise and unstable operation due to the junction termination portion 203 can be reduced.

### Third Embodiment

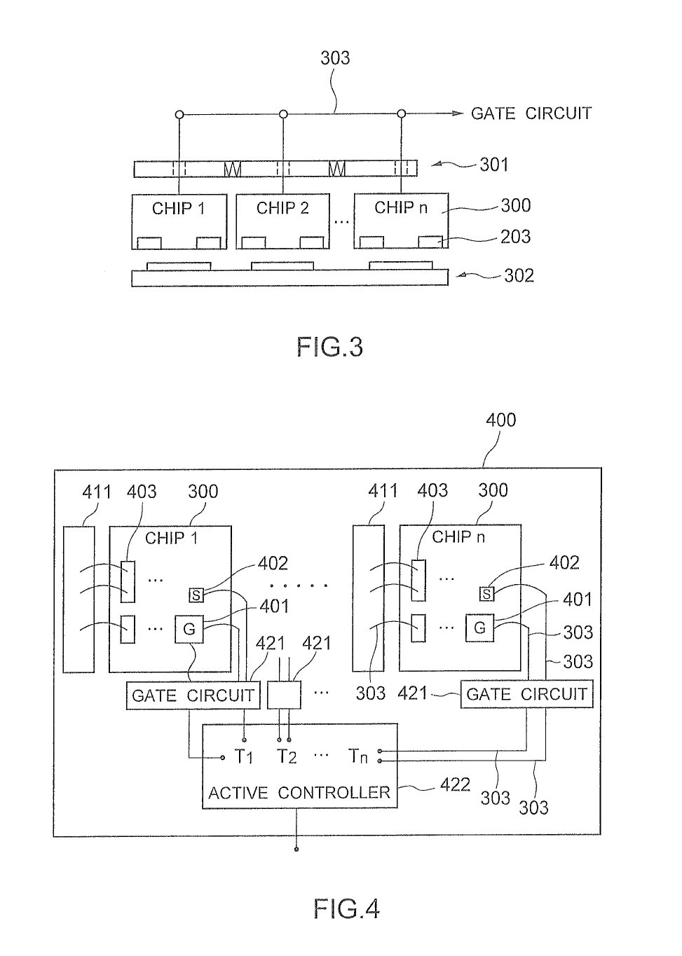

FIG. 3 is a sectional view schematically showing a structure of a semiconductor module of a third embodiment.

The semiconductor module of FIG. 3 includes a plurality of semiconductor chips 300, a cathode unit 301 and an anode unit 302.

Each semiconductor chip 300 of FIG. 3 corresponds to the semiconductor device shown in FIG. 1 or 2. In the present embodiment, plural semiconductor chips 300 are combined to form one semiconductor module. The number “n” of the semiconductor chips 300 is, for example, 20 to 30. FIG. 3 shows the junction termination portions 203 of the respective semiconductor chips 300.

The cathode unit 301 is disposed on the first main surface (S₁) sides of the semiconductor chips 300, whereas the anode unit 302 is disposed on the second main surface (S₂) sides of the semiconductor chips 300. The cathode unit 301 and the anode unit 302 are connected to the first and second main electrodes 121 and 122 of the semiconductor chips 300, respectively. The cathode unit 301 and the anode unit 302 control the semiconductor chips 300 to operate the semiconductor chips 300 as diodes.

Each semiconductor chip 300 of FIG. 3 is connected to a gate circuit which will be described later by a bonding wire 303. It should be noted that the junction termination portions 203 of the present embodiment are provided on the second main surface (S₂) sides of the semiconductor chips 300, so that the bonding wire 303 does not be disposed across the junction termination portions 203.

For convenience of preparing the drawing, a plurality of bonding wires 303 are illustrated by being combined into one in FIG. 3. More detailed disposition of the bonding wires 303 will be described with FIG. 4.

FIG. 4 is a plan view showing the structure of the semiconductor module of the third embodiment. FIG. 4 shows the semiconductor module of FIG. 3 seen in plan view.

The semiconductor module of FIG. 4 includes a plurality of semiconductor chips 300, a plurality of external lead-out electrodes 411 connected to the semiconductor chips 300, a plurality of gate circuits 421 connected to the semiconductor chips 300, an active controller 422 connected to the gate circuits 421, and a package 400 which contains them. The gate circuits 421 are an example of controllers of the disclosure.

Each semiconductor chip 300 includes a gate pad 401, a sense pad 402, and a plurality of electrodes 403 which are provided on the first main surface (Sᵢ) side.

The gate pad 401 is connected to the gate electrodes 112 of the respective MOSFETs shown in FIG. 1 or 2. The sense pad 402 is connected to a certain MOSFET (a MOSFET which functions as a state detector) in FIG. 1 or 2. The gate pad 401 and the sense pad 402 are connected to a corresponding gate circuit 421 by the bonding wires 303. The gate pad 401 is an example of a control electrode pad of the disclosure.

Each electrode 403 corresponds to the first main electrode 121 shown in FIG. 1 or 2. The external lead-out electrodes 411 are connected to the electrodes 403 by the bonding wires 303.

Each gate circuit 421 is connected to a corresponding semiconductor chip 300 by the bonding wires 303, and controls the MOSFETs in the corresponding semiconductor chip 300. More specifically, each gate circuit 421 applies a gate voltage to the gate electrodes 112 via the gate pad 401 to control the MOSFETs. Each gate circuit 421 accesses the state detector via the sense pad 402 to detect a state in the corresponding semiconductor chip 300. Examples of the state detected by each gate circuit 421 include a current, a voltage, a temperature and the like in the corresponding semiconductor chip 300. When the temperature is to be detected, the diode in the semiconductor substrate 100 is used. The gate voltage is an example of a control voltage of the disclosure.

The active controller 422 controls the gate circuits 421 to operate the semiconductor chips 300. The active controller 422 controls the gate circuits 421 by active control based on the detection results of the states in the semiconductor chips 300, which are provided from the gate circuits 421. Therefore, the active controller 422 controls the gate circuits 421 based on the states in the semiconductor chips 300 which change in accordance with time, in addition to the initial set values. Such control has the advantage of being able to suppress variations of the operation of the semiconductor chips 300 by variations of the states in the individual semiconductor chips 300.

Effects of providing the junction termination portions 203 on the second main surface (S₂) sides of the respective semiconductor chips 300 in the semiconductor module of FIG. 4 will now be described.

In a case where the junction termination portions 203 are provided on the first main surface (Sᵢ) sides, the bonding wires 303 which connect the semiconductor chips 300 and the gate circuits 421 are disposed across the junction termination portions 203. Therefore, noise is likely to be added to the signals on the bonding wires 303 in this case. Furthermore, a distance between each junction termination portion 203 and the active controller 422 becomes short in this case, so that noise is also likely to be added to the signals on the bonding wires 303 which connect each gate circuit 421 and the active controller 422.

In this case, if noise is added to the signals for operation control of the semiconductor chips 300 and the gate circuits 421, it is afraid that variations in operation of the semiconductor chips 300 cannot be suppressed.

Therefore, the junction termination portions 203 in the present embodiment are provided on the second main surface (S₂) sides of the respective semiconductor chips 300. Therefore, according to the present embodiment, noise of the signals can be reduced, and variations in operation of the semiconductor chips 300 can be suppressed.

Dynamic characteristics (behavior) variations among the semiconductor chips 300 are desirably suppressed to within, for example, 5%. According to the semiconductor module of the present embodiment, such control can be realized.

### Fourth and Fifth Embodiments

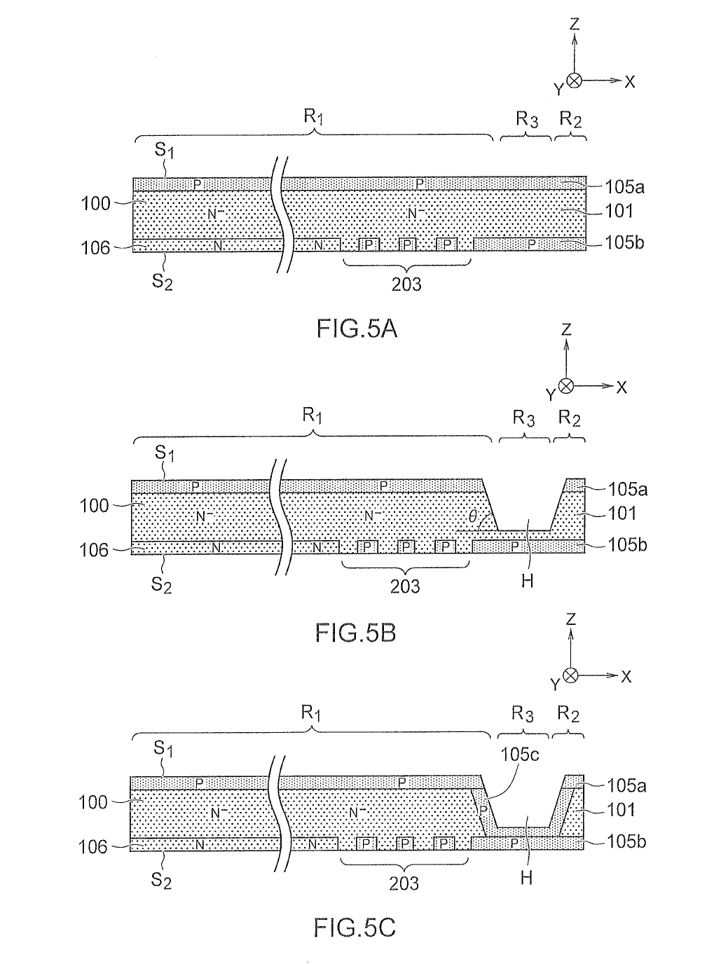

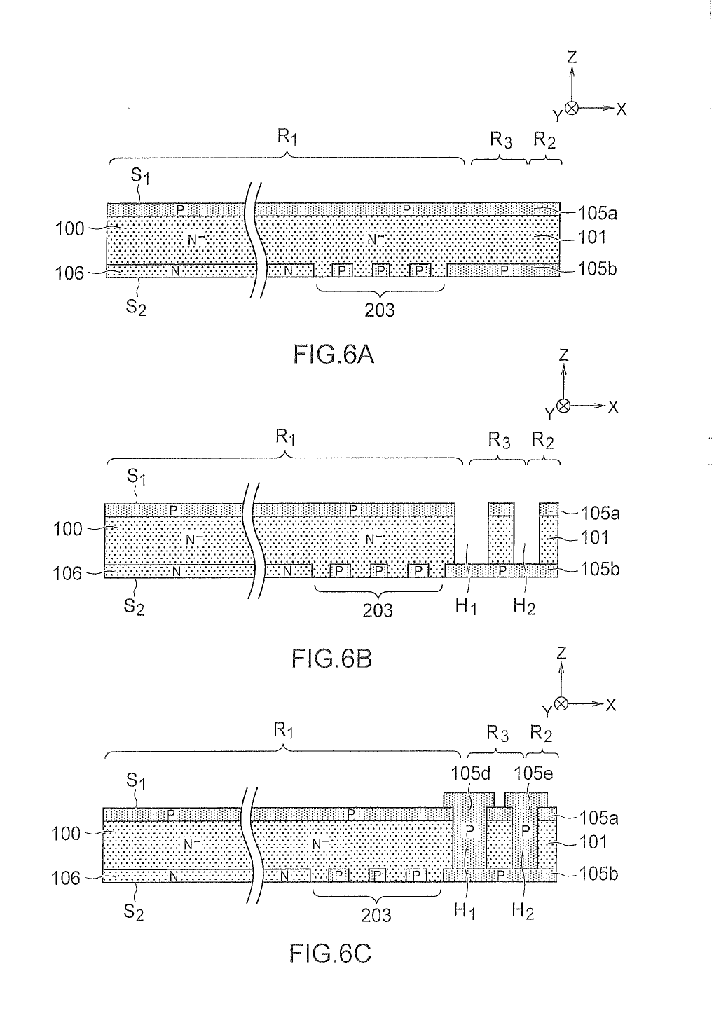

In fourth and fifth embodiments, examples of a method of manufacturing the semiconductor device of FIG. 1 will be described with reference to FIGS. 5A to 6C.

FIGS. 5A to 5C are sectional views showing an outline of the method of manufacturing the semiconductor device of the fourth embodiment.

First, the first base layer 101 is formed in the semiconductor substrate 100 (FIG. 5A). A P type diffusion layer 105a and the like to be a portion of the peripheral diffusion layer 105 are then formed on the surface of the first base layer 101 on the first main surface (Sᵢ) side (FIG. 5A). A P type diffusion layer 105b to be a portion of the peripheral diffusion layer 105, the junction termination portion 203, the anode layer 106 and the like are then formed on the surface of the first base layer 101 on the second main surface (S₂) side. In FIG. 5A, reference signs R₁ and R₂ denote chip regions, and reference sign R₃ denotes a dicing region.

A trench H is then formed in the dicing region R₃ of the semiconductor substrate 100 (FIG. 5B). Reference sign B denotes an inclination angle of a side surface of the trench H. The inclination angle θ is desirably set at a value close to 90 degrees. In the present embodiment, the trench H is formed on the first main surface (Sᵢ) side, but the trench H may be formed on the second main surface (S₂) side.

A P type diffusion layer 105c to be a portion of the peripheral diffusion layer 105 is then formed on side surfaces and a bottom surface of the trench H (FIG. 5C). The P type diffusion layer 105c is formed to be in contact with the P type diffusion layers 105a and 105b.

Thereafter, in the present embodiment, the first and second main electrodes 121 and 122 and the like are formed, and the semiconductor substrate 100 is then cut in the dicing region R₃. In this manner, the semiconductor device of FIG. 1 is manufactured.

FIGS. 6A to 6C are sectional views showing an outline of the method of manufacturing the semiconductor device of the fifth embodiment.

First, a structure shown in FIG. 6A is formed as similar to the fourth embodiment.

Trenches H₁ and H₂ are then formed on a border between the chip region R₁ and the dicing region R₃ and on a border between the chip region R₂ and the dicing region R₃, respectively (FIG. 6B). In the present embodiment, the trenches H₁ and H₂ are formed on the first main surface (Sᵢ) side, but the trenches H₁ and H₂ may be formed on the second main surface (S₂) side.

P type diffusion layers 105d and 105e to be portions of the peripheral diffusion layer 105 are then formed in the trenches H₁ and H₂ (FIG. 6C). The P type diffusion layers 105d and 105e are formed to be in contact with the P type diffusion layers 105a and 105b.

Thereafter, in the present embodiment, the first and second main electrodes 121 and 122 and the like are formed, and the semiconductor substrate 100 is then cut in the dicing region R₃. In this manner, the semiconductor device of FIG. 1 is manufactured.

As described above, according to the fourth or fifth embodiment, the peripheral diffusion layer 105 can be formed on the side surfaces of the semiconductor substrate 100 to manufacture the semiconductor device of FIG. 1. The fourth and the fifth embodiments can be also applied to manufacture the semiconductor device of FIG. 2.

### Sixth Embodiment

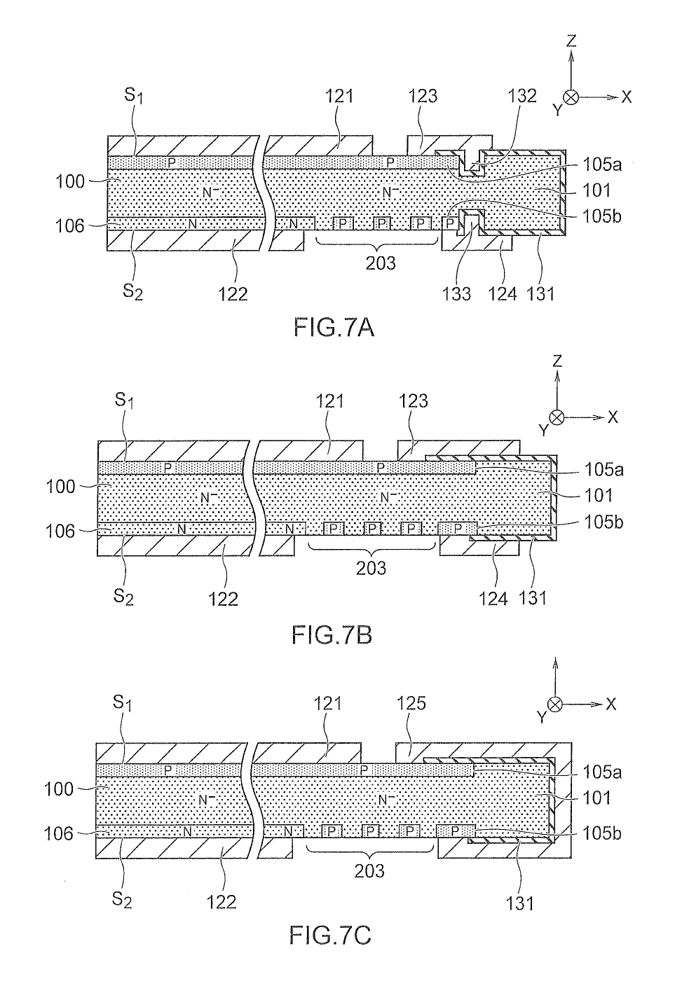

FIGS. 7A to 7C are sectional views showing structures of semiconductor devices of a sixth embodiment.

In FIG. 7A, although the peripheral diffusion layer 105 is formed on the first and second main surfaces S₁ and S₂ of the semiconductor substrate 100, the peripheral diffusion layer 105 is not formed on the side surfaces of the semiconductor substrate 100. Instead, the semiconductor device of FIG. 7A includes main electrodes 123 and 124, an insulator 131, and trenches 132 and 133.

The trenches 132 and 133 are formed on the first and second main surfaces Sᵢ and S₂ sides of the semiconductor substrate 100, respectively. The insulator 131 is continuously formed on the first and second main surfaces Sᵢ and S₂ and the side surface in the vicinity of the side surface of the semiconductor substrate 100. A part of the insulator 131 is also formed on side surfaces and bottom surfaces of the trenches 132 and 133.

The main electrodes 123 and 124 are formed on the first and second main surfaces Sᵢ and S₂ sides of the semiconductor substrate 100, respectively. Parts of the main electrodes 123 and 124 are also embedded in the trenches 132 and 133 via the insulator 131, respectively.

The main electrodes 123 and 124 are connected to a source line, similarly to the first main electrode 121. Therefore, the junction termination portion 203 of FIG. 7A is disposed between a layer connected to the source line, and a layer connected to the drain electrode (second main electrode) 122, similarly to the junction termination portions 203 in FIGS. 1 and 2. Therefore, according to the present embodiment, the junction termination portion 203 can be made to function as similar to those in the first and second embodiments.

In the present embodiment, a structure in which the trenches 132 and 133 are not provided may be adopted as shown in FIG. 7B. In the present embodiment, the main electrodes 123 and 124 may be replaced with one main electrode 125 as shown in FIG. 7C. The main electrode 125 of FIG. 7C is continuously formed on the first and second main surfaces Sᵢ and S₂ and the side surface of the semiconductor substrate 100.

As described above, according to the sixth embodiment, the junction termination portion 203 can be formed on the second main surface (S₂) side without forming the peripheral diffusion layer 105 on the side surface of the semiconductor substrate 100.

### Seventh Embodiment

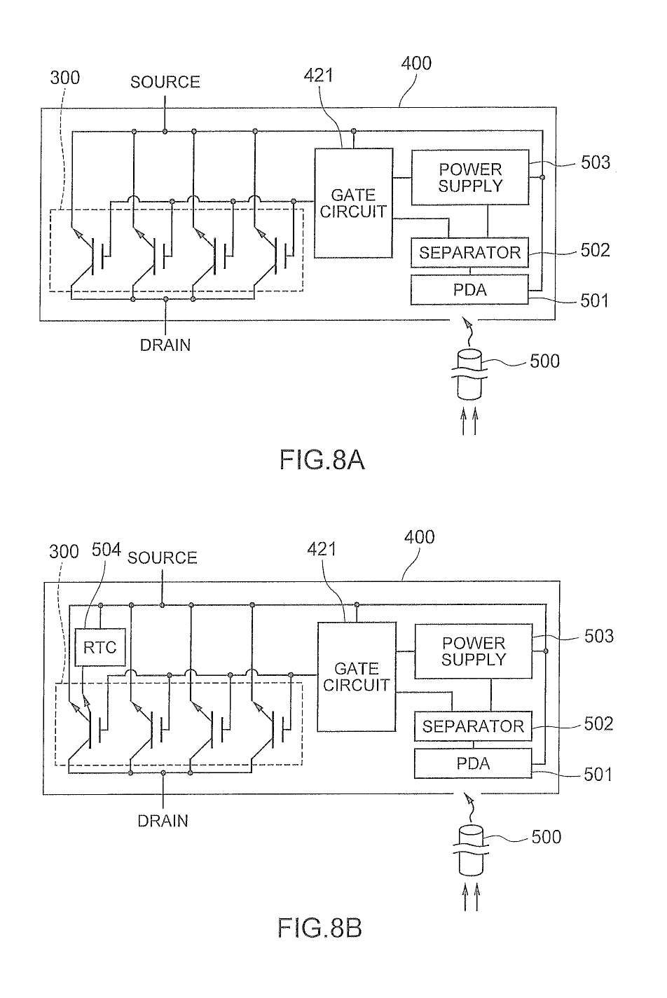

In a seventh embodiment, examples of a semiconductor module in which the active controller 422 is disposed outside the package 400 will be described with reference to FIGS. 8A to 10B.

FIGS. 8A to 10B are circuit diagrams showing the examples of the structure of the semiconductor module of the seventh embodiment.

The semiconductor module of FIG. 8A includes semiconductor chips 300, gate circuits 421, a photo diode array (PDA) 501 as an example of a light receiving device, a separator 502, a power supply 503, and the package 400 which contains them. FIG. 8A shows one semiconductor chip 300 and one gate circuit 421 as examples.

The semiconductor module of FIG. 8A further includes the active controller 422 (not illustrated) which is disposed outside the package 400, and an optical fiber 500 which is disposed between the package 400 and the active controller 422.

The optical fiber 500 of FIG. 8A irradiates the PDA 501 with light containing a first optical component which contains a signal from the active controller 422 to the gate circuits 421, and a second optical component for power supplying to the gate circuits 421. The PDA 501 receives the light to convert the light into an electric signal. The separator 502 separates the electric signal into the signal component to the gate circuits 421, and the component for the power supplying to the gate circuits 421. The former signal component is supplied to the gate circuits 421, and the latter component is supplied to the power supply 503. The power supply 503 is an electric power supply circuit including, for example, a capacitor and a secondary battery, and supplies electric power to the gate circuits 421.

According to the structure of FIG. 8A, control of the gate circuits 421 and the power supplying to the gate circuits 421 are performed with the optical signal, so that the active controller 422 can be disposed outside the package 400. Therefore, the active controller 422 is disposed away from the junction termination portions 203 so that signal noise can be further reduced and variations in operation of the semiconductor chips 300 can be more effectively suppressed.

In the semiconductor module of FIG. 8A, the semiconductor chips 300 may be disposed in different packages 400. In this case, each package 400 contains one semiconductor chip 300, one gate circuit 421, the PDA 501, the separator 502 and the power supply 503. The same applies to semiconductor modules of FIGS. 8B to 10B which will be described later.

The semiconductor modules of FIGS. 8B to 10B will now be described.

In FIG. 8B, a real time controller (RTC) 504 is connected to a transistor which functions as the state detector. In order to suppress variations in operation of the semiconductor chips 300 continuously, the state detector is desirably controlled by real time control which immediately performs required processing. According to the structure of FIG. 8B, such real time control can be executed.

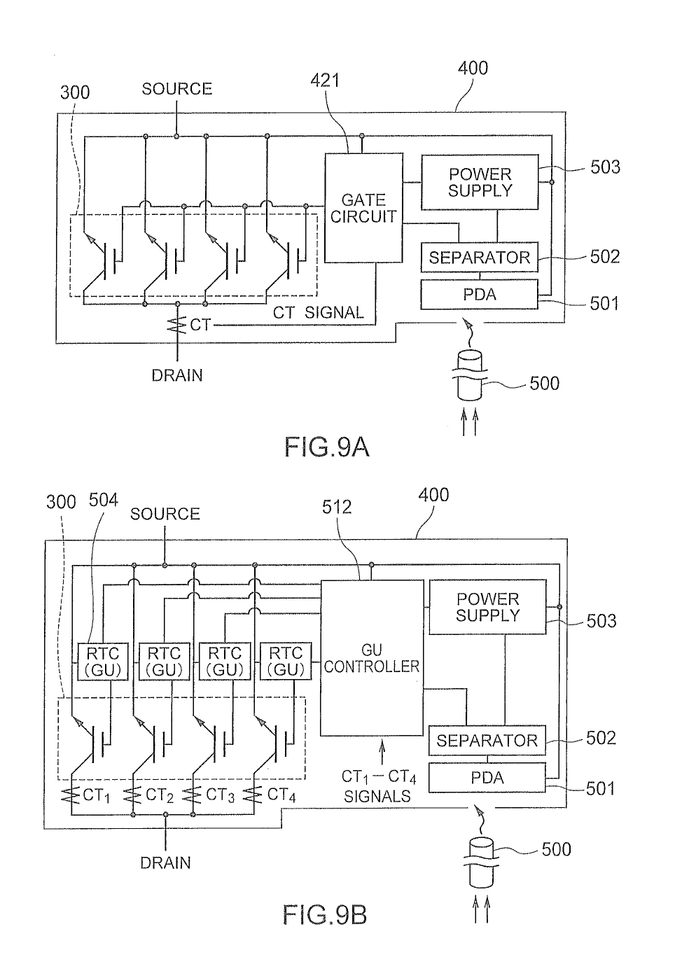

In FIG. 9A, a current sensor (current transformer) CT is connected to the semiconductor chips 300. The current sensor CT is disposed on a current path in the package 400 and supplies detection results of a current to the gate circuits 421. The gate circuit 421 of FIG. 9A supply the detection results of the current by the current sensor CT to the active controller 422, instead of the detection results of the states in the semiconductor chips 300. Variations in operation of the semiconductor chips 300 can be recognized from not only the currents which flow in the semiconductor chips 300, but also the current which flows on the current path connected to the semiconductor chips 300. Therefore, according to the structure of FIG. 9A, the active control of the gate circuits 421 can be performed to suppress the variations in operation of the semiconductor chips 300 as similar to the third embodiment. In FIG. 9A, the sense pads 402 of the semiconductor chips 300 are not required.

In FIG. 9B, current sensors CT are connected to the respective transistors in the semiconductor chips 300. According to the structure of FIG. 9B, currents can be detected at a plurality of spots in the package 400, so that more precise active control can be performed.

In FIG. 9B, RTCs 504 which has the functions of the gate circuits (GU) 421 are connected to the respective transistors in the semiconductor chips 300. Therefore, in FIG. 9B, the gate circuits 421 in FIG. 9B are replaced with GU controllers 512 which control the semiconductor chips 300 and the RTCs 504. A circuit including the RTCs 504 and the GU controllers 512 is an example of a controller of the disclosure, similarly to a gate circuit 421. According to the structure of FIG. 9B, much more processing can be made the target of the real time control than in the case of FIG. 8B.

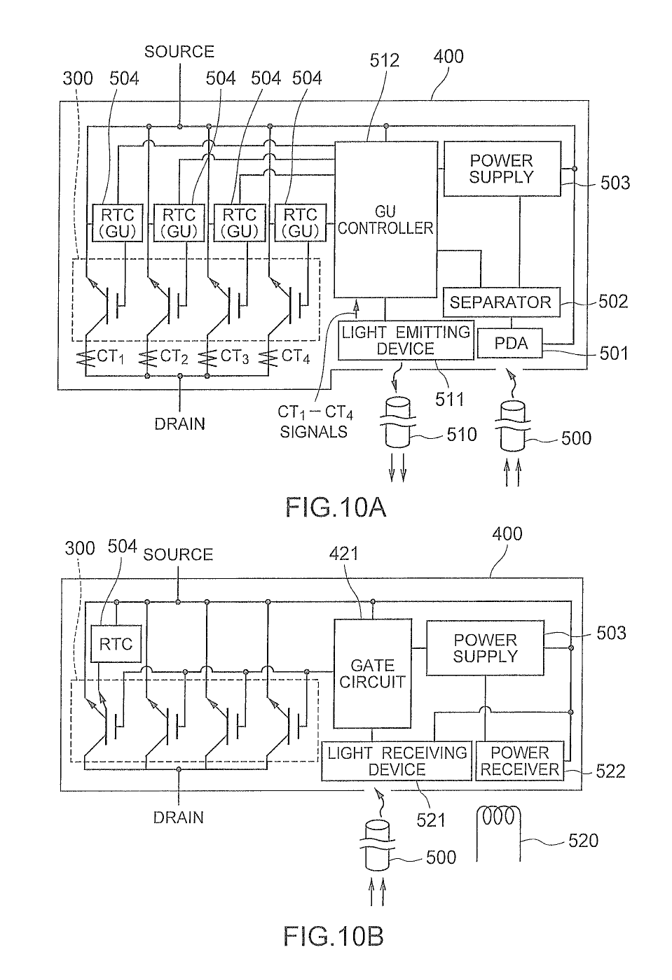

A semiconductor module of FIG. 10A includes an optical fiber 510 disposed outside the package 400, and a light emitting device 511 disposed in the package 400. The light emitting device 511 is connected to the GU controllers 512, and emits light which contains a signal to the active controller 420 from the GU controllers 512. The light is supplied to the active controller 422 through the optical fiber 510. According to the structure of FIG. 10A, the detection results of the states in the semiconductor chips 300 or the state in the package 400 can be exchanged by an optical signal, so that signal noise can be further reduced.

A semiconductor module of FIG. 10B includes a power supply module 520 disposed outside the package 400, and a light receiving device 521 and a power receiver 522 which are disposed in the package 400. In FIG. 10B, exchange of a signal for controlling the gate circuits 421, and exchange of energy for the power supplying to the gate circuits 421 are separately performed. More specifically, the former is performed between the optical fiber 500 and the light receiving device 521, and the latter is performed between the power supply module 520 and the power receiver 522. The power receiver 522 receives power by noncontact power supplying from the power supply module 520. According to the structure of FIG. 10B, an optional noncontact power supplying method can be adopted, and therefore, a power supplying method which is more efficient than optical power supplying can be adopted in accordance with necessity. In the semiconductor module of FIG. 10B, the separator 502 is not required.

In the present embodiment, two or more of the structures shown in FIGS. 8A to 10B may be combined and adopted. For example, the light emitting device 511 of FIG. 10A can be also applied to the semiconductor modules other than FIG. 10A.

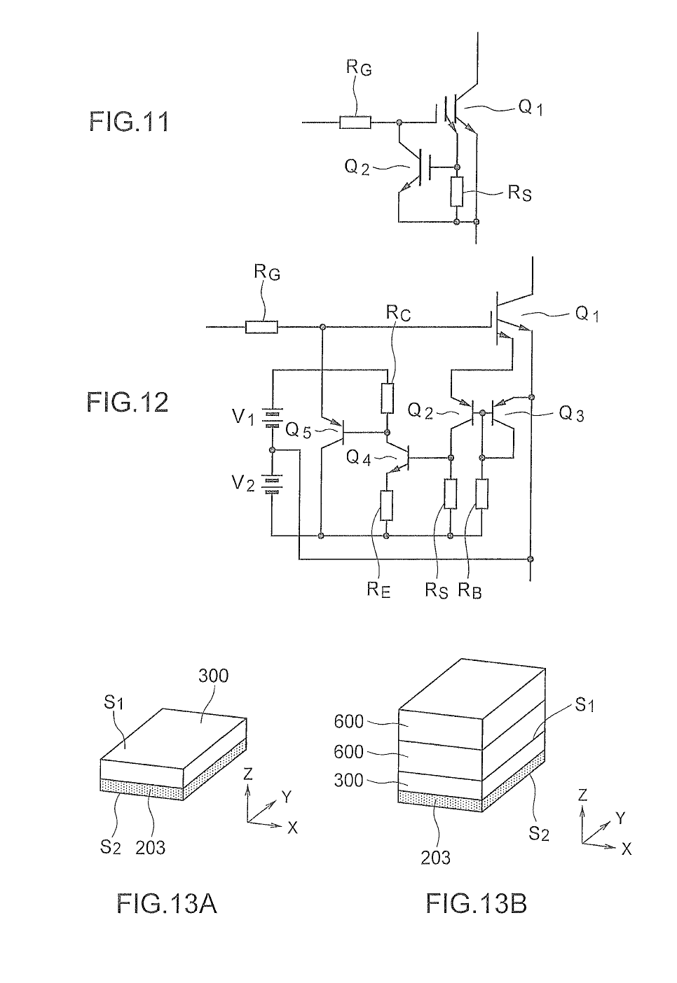

In the present embodiment, a short-circuit protection circuit for protecting the transistors may be interposed in the position of the RTC(s) 504. FIGS. 11 and 12 are circuit diagrams showing examples of such short-circuit protection circuit. Reference signs Q, R and V denote a transistor, a resistor and a power supplying, respectively. In the present embodiment, any one of the short-circuit protection circuits of FIGS. 11 and 12 may be adopted, but for protection of the transistors shown in FIG. 1 or 2, the short-circuit protection circuit of FIG. 12 is more preferably adopted.

As described above, according to the present embodiment, the active controller 422 can be disposed outside the package 400. Therefore, according to the present embodiment, the active controller 422 is disposed separately from the junction termination portions 203, so that the signal noise can be reduced, and variations in operation of the semiconductor chips 300 can be suppressed.

### Modifications of First to Seventh Embodiments

FIGS. 13A and 13B are perspective views showing examples of a method of mounting semiconductor devices of the first to the seventh embodiments.

FIG. 13A shows the semiconductor chip (semiconductor device) 300 of any one of the first to the seventh embodiments. The semiconductor chip 300 of FIG. 13A has the junction termination portion 203 on the second main surface (S₂) side. Therefore, even when other semiconductor chips 600 are stacked on the first main surface S₁ of the semiconductor chip 300 as shown in FIG. 13B, the influence which the junction termination portion 203 has on the semiconductor chips 600 is small.

Therefore, in the first to the seventh embodiments, the method of mounting shown in FIG. 13B may be adopted. Thereby, the semiconductor chips 300 and 600 can be contained in the compact package 400.

The semiconductor chips 600 have structures different from that of the semiconductor chip 300. For example, the semiconductor chips 600 are configured to operate with lower device operation voltages than the semiconductor chip 300. An example of the semiconductor chips 600 includes semiconductor chips whose main material is Si (silicon). In this case, an example of the semiconductor chip 300 includes a semiconductor chip whose main material is SiC (silicon carbide) or GaN (gallium nitride). A low voltage MOSFET, a diode, a PDA, a control IC or the like may be stacked on the semiconductor chip 300, instead of or with the semiconductor chips 600.

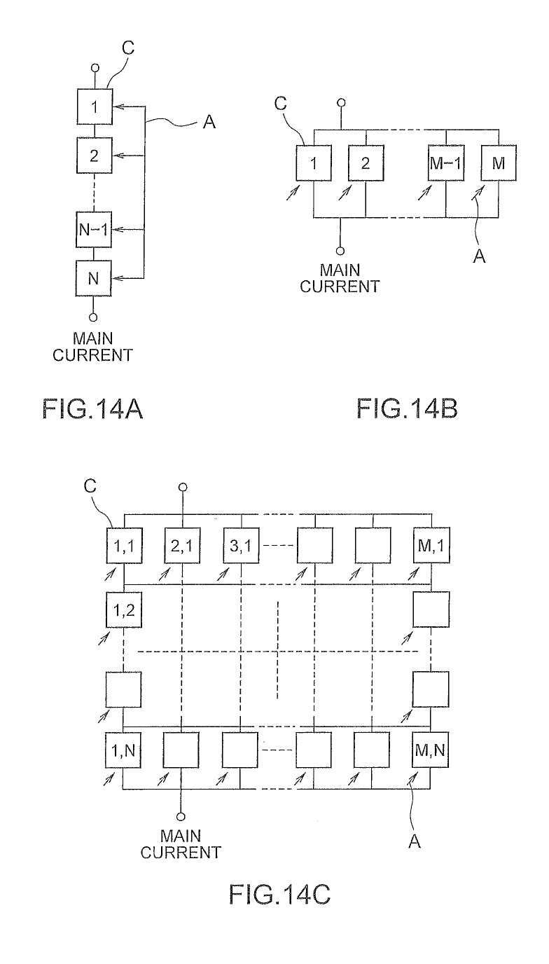

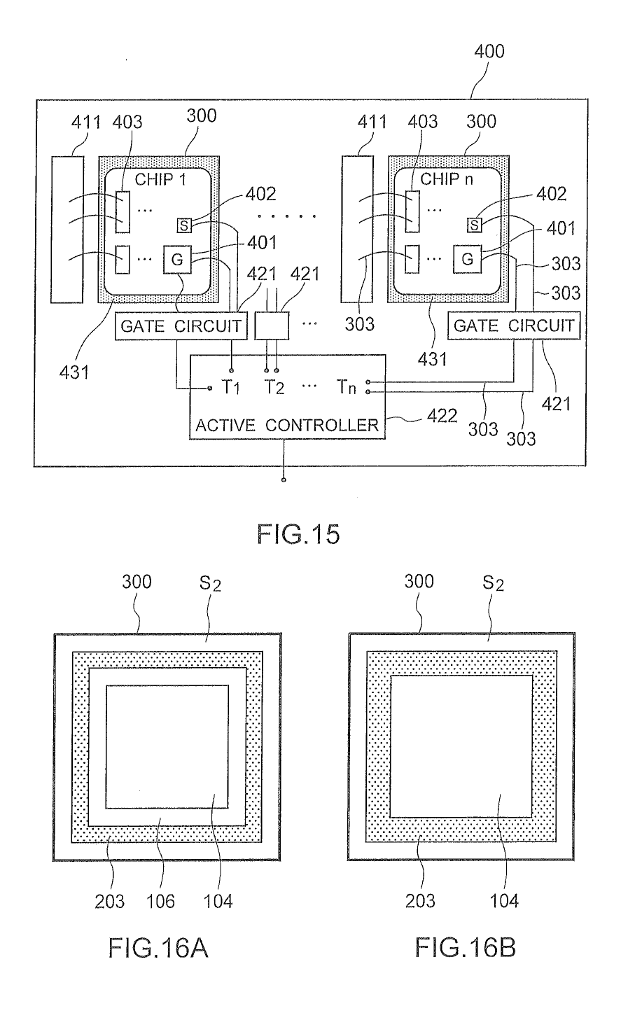

FIGS. 14A to 14C are schematic views showing examples of a method of connecting semiconductor structures C of the first to the seventh embodiments. Each semiconductor structure C of FIGS. 14A to 14C corresponds to the semiconductor chip 300 shown in FIG. 13A, the combined unit of the semiconductor chips 300 and 600 shown in FIG. 13B, or the semiconductor module shown in FIG. 4 or the following FIG. 15.

FIG. 14A shows an example in which N semiconductor structures C are connected in series, where N is an integer of 2 or more. The arrows “A” indicate control signals and electric power supplied to the semiconductor structures C. The signals and power are supplied by light (LED light, laser light or the like) or electrical noncontact (radio or the like) or the like, for example, by the method of the seventh embodiment.

The semiconductor structures C may be connected to each other by parallel connection as shown in FIG. 14B. FIG. 14B shows an example in which M semiconductor structures C are connected in parallel, where M is an integer of 2 or more.

The semiconductor structures C may be connected to each other by combination of series connection and parallel connection. One example thereof is shown in FIG. 14C. FIG. 14C shows an example in which M×N semiconductor structures C are connected by series connection and parallel connection.

FIG. 15 is a plan view showing a structure of a semiconductor module of a modification of the third embodiment.

Each semiconductor chip 300 of FIG. 15 includes a junction termination portion 431 on the first main surface (S₁) side, instead of the second main surface (S₂) side. Therefore, the signals on the bonding wires 303 in the package 400 are susceptible to the influence of the junction termination portions 431 as compared with the case of FIG. 4.

However, if the structure shown in, for example, any one of FIGS. 8A to 10B are applied to the semiconductor module of the present modification, the influence of the junction termination portions 431 can be reduced, and therefore signal noise and unstable operation can be sufficiently reduced in some cases while the structure of the present modification is adopted. Also, when the variation suppression effect of the chip operation is sufficiently obtained by the active control, the influence of the junction termination portions 431 can be ignored in some cases. Therefore, in the cases like those examples, the structure of FIG. 15 may be adopted.

### Eighth Embodiment

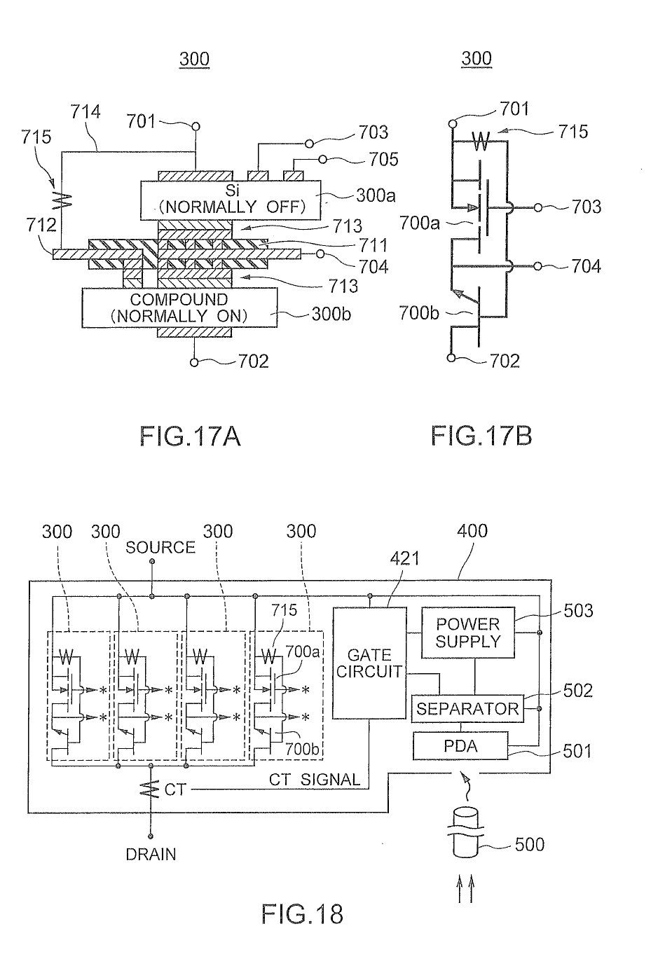

FIGS. 17A and 17B are a schematic view and a circuit diagram showing a cross section and a circuit structure of a semiconductor chip 300 of an eighth embodiment, respectively. The semiconductor chip 300 of FIG. 17A corresponds to one of the semiconductor chips 300 shown in FIG. 4 or FIG. 15. FIG. 17B is a circuit diagram showing the semiconductor chip 300 of FIG. 17A.

As shown in FIG. 17A, the semiconductor chip 300 of the present embodiment is configured by bonding two semiconductor chips 300a and 300b, and further includes a source terminal 701, a drain terminal 702, a gate terminal 703, a voltage sensing terminal 704, a current sensing terminal 705, an insulator substrate 711, wirings 712, a wiring 714 such as a bonding wire, and a current sensor 715. Hereinafter, the semiconductor chips 300a and 300b are referred to as first and second semiconductor chips, respectively.

The first and second semiconductor chips 300a and 300b are power semiconductor devices. At least one of the first and second semiconductor chips 300a and 300b may have the structure shown in FIG. 1 or FIG. 2.

The first and second semiconductor chips 300a and 300b are bonded via the insulator substrate 711 with each other, and electrically connected with each other via the wirings 712 and 714. The numerals 713 denote bonded places of electrodes by soldering or the like in the insulator substrate 711. The current sensor 715 is configured to detect a current flowing in the wiring 714, and is used to feed back a detection result of the current to the control of the semiconductor chip 300. The current sensor 715 may be replaced with a resistor for current sensing.

The first semiconductor chip 300a includes a plurality of Si-type transistors integrated to be disposed in parallel, and corresponds to a numeral 700a in FIG. 17B. In FIG. 17B, the first semiconductor chip 300a including the plurality of transistors is denoted by one semiconductor symbol with the numeral 700a for convenience sake for the drawing. The first semiconductor chip 300a (700a) functions as a normally-off device as a whole which is turned off when the gate voltage is zero. The transistors of the first semiconductor chip 300a are formed of an Si substrate or an Si layer, and each of the transistors is a normally-off transistor, for example.

The second semiconductor chip 300b includes a plurality of compound-type transistors integrated to be disposed in parallel, and corresponds to a numeral 700b in FIG. 17B. In FIG. 17B, the second semiconductor chip 300b including the plurality of transistors is denoted by one semiconductor symbol with the numeral 700b for convenience sake for the drawing. The second semiconductor chip 300b (700b) functions as a normally-on device as a whole which is turned on when the gate voltage is zero. The transistors of the second semiconductor chip 300b are formed of a compound semiconductor substrate or a compound semiconductor layer, and each of the transistors is a normally-on transistor, for example. Examples of the compound semiconductor include SiC and GaN.

As shown in FIG. 17A, the first semiconductor chip 300a as a normally-off device and the second semiconductor chip 300b as a normally-on device are cascaded in the present embodiment. Therefore, when the semiconductor chip 300 is regarded as one device, this device functions as a normally-off device as a whole.

Effects of the eighth embodiment are now described.

When a compound-type device is manufactured, it is generally easier to manufacture a normally-on device than a normally-off device. Furthermore, the compound-type device having high performance can be generally realized easier by the normally-on device than the normally-off device. Therefore, the second semiconductor chip 300b in the present embodiment is a normally-on device to realize the semiconductor chip 300 having high performance.

However, if the semiconductor chip 300 is a normally-on device, the control electrode of the semiconductor chip 300 needs to be continuously applied with a voltage to switch off the semiconductor chip 300. Therefore, the first semiconductor chip 300a is a normally-off device and the first and second semiconductor chips 300a and 300b are cascaded with each other in the present embodiment so that the semiconductor chip 300 becomes a normally-off device.

As a result, the semiconductor chip 300 of the present embodiment is configured by bonding the first and second semiconductor chips 300a and 300b. In other words, the semiconductor chip 300 of the present embodiment is not formed of one chip but is formed of two chips. Therefore, in a case where a semiconductor module is formed by connecting the semiconductor chips 300 of the present embodiment in parallel to deal with a large amount of current, noise and an uneven current or voltage are easily generated compared to a case where a semiconductor module is formed by connecting semiconductor chips of one-chip type in parallel. Furthermore, in the case where a semiconductor module is formed by connecting the semiconductor chips 300 of the present embodiment in parallel, noise is easily applied to signals on bonding wires near the semiconductor chips 300. Therefore, when a semiconductor module is configured by using the semiconductor chips 300 of the present embodiment, the semiconductor module is preferred to have the structure shown in FIG. 4 or FIG. 15. This makes it possible to suppress variations in operation of the semiconductor chips 300 and variations in operation of the semiconductor chips 300a, 300b in the same semiconductor chip 300 and in different semiconductor chips 300 in the semiconductor module. Furthermore, the present embodiment can allow more active operation control than ever as necessary.

In the present embodiment, the transistors in the first semiconductor chip 300a of normally-off type may be compound-type transistors. However, the Si-type transistors in the first semiconductor chip 300a of normally-off type have a benefit that the cost of the first semiconductor chip 300a can be reduced easier than the compound-type transistors in the first semiconductor chip 300a of normally-off type.

In the present embodiment, the transistors in the second semiconductor chip 300b of normally-on type may be Si-type transistors. However, the compound-type transistors in the second semiconductor chip 300b of normally-on type have a benefit that the transistors having high performance can be realized easier than the Si-type transistors in the second semiconductor chip 300b of normally-on type.

The semiconductor chip 300 may be configured by cascading three or more semiconductor chips. In this case, at least one of these semiconductor chips of the semiconductor chip 300 is a normally-off device, and the remaining semiconductor chip(s) is/are normally-on device(s) in the present embodiment. The transistors of these semiconductor chips may be replaced with normally-off or normally-on devices other than the transistors. Regarding the breakdown voltage of the transistors, the breakdown voltage of the transistors in the second semiconductor chip 300b is preferred to be higher than the breakdown voltage of the transistors in the first semiconductor chip 300a, but may be lower than the breakdown voltage of the transistors in the first semiconductor chip 300a depending on applications of the semiconductor chip 300.

FIGS. 18 to 20 are circuit diagrams showing examples of a structure of a semiconductor module of the eighth embodiment.

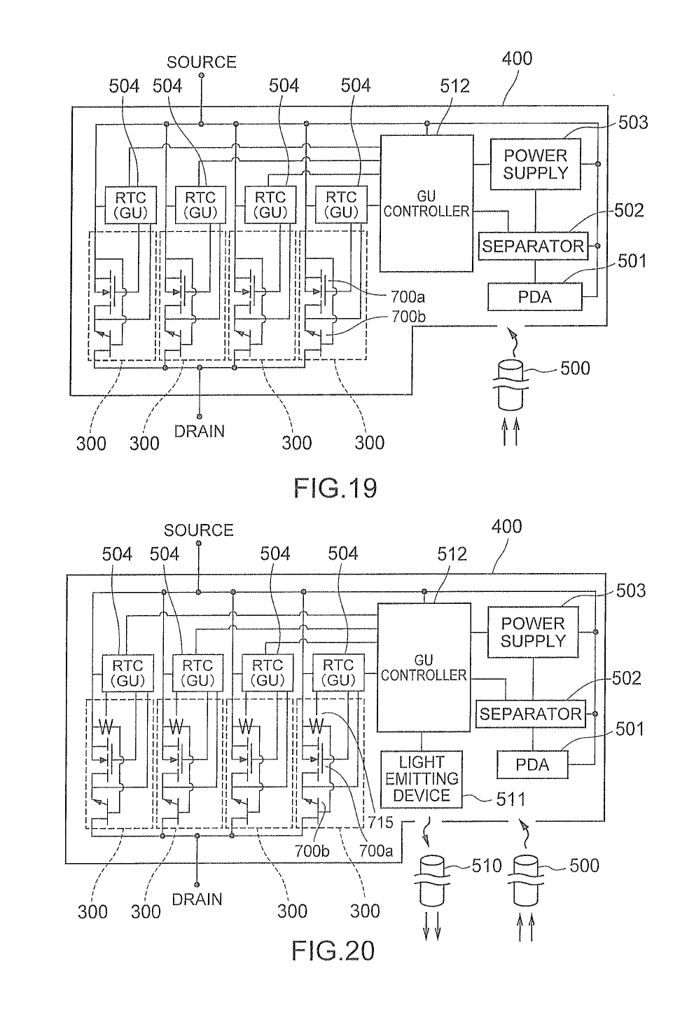

The semiconductor module of FIG. 18 has a structure that the semiconductor chip 300 in the semiconductor module of FIG. 9A is replaced with one or more (four in here) semiconductor chips 300 of the present embodiment. The semiconductor module of FIG. 19 or FIG. 20 has a structure that a semiconductor chip 300 in a semiconductor module similar to that of FIG. 9B or FIG. 10A is replaced with one or more semiconductor chips 300 of the present embodiment. In this manner, the structures of the semiconductor module or the like in the first to seventh embodiments can be also applied to the eighth embodiment.

Nodes denoted by symbols “*” in FIG. 18 are connected to the gate circuit(s) 421. The numeral 421 in FIG. 18 is intended to denote the gate circuits 421 whose total number is as same as the total number of the semiconductor chips 300. These gate circuits 421 may be disposed near the respective corresponding semiconductor chips 300, or may be disposed in the same place together. This is also applied to the numeral 512 in FIGS. 19 and 20.

As described above, the semiconductor chip 300 in the present embodiment is configured by cascading K semiconductor chips where K is an integer of two or more. In the present embodiment, at least one of these semiconductor chips of the semiconductor chip 300 functions as a normally-off device. Therefore, according to the present embodiment, the semiconductor chip 300 can be a normally-off device while the semiconductor chip 300 can have high performance.

In the present embodiment, when a semiconductor module is configured by using such semiconductor chips 300, the structure of the semiconductor module shown in FIG. 4 or FIG. 15 is adopted. This makes it possible to actively suppress variations in operation of the semiconductor chips 300 and variations in operation of the semiconductor chips 300a, 300b in the same semiconductor chip 300 and in different semiconductor chips 300 in the semiconductor module of the present embodiment, so that the performance of the semiconductor module can be significantly improved.

While certain embodiments have been described, these embodiments have been presented by way of example only, and are not intended to limit the scope of the inventions. Indeed, the novel devices and modules described herein may be embodied in a variety of other forms; furthermore, various omissions, substitutions and changes in the form of the devices and modules described herein may be made without departing from the spirit of the inventions. The accompanying claims and their equivalents are intended to cover such forms or modifications as would fall within the scope and spirit of the inventions.

1. A semiconductor device comprising:
a semiconductor substrate having first and second main surfaces, and including a first semiconductor layer of a first conductivity type disposed in the semiconductor substrate, a second semiconductor layer of a second conductivity type disposed on a surface of the first semiconductor layer on a first main surface side, a third semiconductor layer of the first conductivity type disposed on a surface of the second semiconductor layer, and a fourth semiconductor layer of the second conductivity type disposed on a surface of the first semiconductor layer on a second main surface side;
a control electrode disposed on the first main surface side of the semiconductor substrate;
a first main electrode disposed on the first main surface side of the semiconductor substrate;
a second main electrode disposed on the second main surface side of the semiconductor substrate; and
a junction termination portion disposed on the second main surface side of the semiconductor substrate, and having an annular planar shape surrounding the fourth semiconductor layer.

2. The device of claim 1, wherein the semiconductor substrate further includes a fifth semiconductor layer of the second conductivity type disposed on a side surface of the semiconductor substrate.

3. The device of claim 2, wherein the junction termination portion is disposed between the fourth and fifth semiconductor layers.

4. The device of claim 2, wherein the semiconductor substrate further includes a sixth semiconductor layer of the first conductivity type disposed between the first and fourth semiconductor layers.

5. The device of claim 4, wherein
the fifth semiconductor layer is disposed on the side surface and the first main surface of the semiconductor substrate,
one of the fifth and sixth semiconductor layers functions as a cathode layer, and
the other of the fifth and sixth semiconductor layers functions as a anode layer.

6. A semiconductor module comprising:
a plurality of semiconductor chips, each of which includes a semiconductor substrate having first and second main surfaces, and a control electrode disposed on a first main surface side of the semiconductor substrate;
a plurality of controllers, each of which is connected to a control electrode pad and a sense pad disposed on the first main surface side of the semiconductor substrate of a semiconductor chip, and configured to apply a control voltage to the control electrode of the semiconductor chip via the control electrode pad and detect a state in the semiconductor chip via the sense pad; and
an active controller configured to control the controllers by active control based on the states in the semiconductor chips.

7. The module of claim 6, wherein each semiconductor chip further includes:
a first main electrode disposed on the first main surface side of the semiconductor substrate;
a second main electrode disposed on a second main surface side of the semiconductor substrate; and
a junction termination portion disposed on the second main surface side of the semiconductor substrate.

8. The module of claim 7, wherein
the semiconductor substrate of each semiconductor chip includes a first semiconductor layer of a first conductivity type disposed in the semiconductor substrate, a second semiconductor layer of a second conductivity type disposed on a surface of the first semiconductor layer on the first main surface side, a third semiconductor layer of the first conductivity type disposed on a surface of the second semiconductor layer, and a fourth semiconductor layer of the second conductivity type disposed on a surface of the first semiconductor layer on the second main surface side, and
the junction termination portion of each semiconductor chip has an annular planar shape surrounding the fourth semiconductor layer.

9. The module of claim 6, wherein each controller detects a current, a voltage or a temperature in the semiconductor chip via the sense pad.

10. The module of claim 6, further comprising a light receiving device configured to receive light which contains a signal to a controller from the active controller.

11. The module of claim 10, wherein the light contains a first optical component containing the signal to the controller from the active controller, and a second optical component for power supplying to the controller.

12. The module of claim 10, further comprising a power receiver other than the light receiving device for receiving power by noncontact power supplying.

13. The module of claim 6, further comprising a light emitting device configured to emit light which contains a signal to the active controller from a controller.

14. The module of claim 6, wherein
at least one of the plurality of semiconductor chips is configured by cascading K semiconductor chips where K is an integer of two or more, and
at least one of the K semiconductor chips functions as a normally-off device.

15. A semiconductor module comprising:
a plurality of semiconductor chips, each of which includes a semiconductor substrate having first and second main surfaces, and a control electrode disposed on a first main surface side of the semiconductor substrate;
a plurality of controllers, each of which is configured to apply a control voltage to the control electrode of a semiconductor chip and detect a state in the semiconductor chip or a state in a package which contains the semiconductor chip; and
an active controller configured to control the controllers by active control based on the states in the semiconductor chips or on the state in the package.

16. The module of claim 15, wherein each semiconductor chip further includes:
a first main electrode disposed on the first main surface side of the semiconductor substrate;
a second main electrode disposed on a second main surface side of the semiconductor substrate; and
a junction termination portion disposed on the second main surface side of the semiconductor substrate.

17. The module of claim 16, wherein
the semiconductor substrate of each semiconductor chip includes a first semiconductor layer of a first conductivity type disposed in the semiconductor substrate, a second semiconductor layer of a second conductivity type disposed on a surface of the first semiconductor layer on the first main surface side, a third semiconductor layer of the first conductivity type disposed on a surface of the second semiconductor layer, and a fourth semiconductor layer of the second conductivity type disposed on a surface of the first semiconductor layer on the second main surface side, and
the junction termination portion of each semiconductor chip has an annular planar shape surrounding the fourth semiconductor layer.

18. The module of claim 15, further comprising a light receiving device configured to receive light which contains a signal to a controller from the active controller.

19. The module of claim 18, wherein the light contains a first optical component containing the signal to the controller from the active controller, and a second optical component for power supplying to the controller.

20. The module of claim 18, further comprising a power receiver other than the light receiving device for receiving power by noncontact power supplying.
